(19) United States
(12) Patent Application Publication
(10) Pub. No.: US 2022/0145151 A1
(43) Pub. Date: May 12, 2022

(54) RESIN SHEET

(71) Applicant: LINTEC CORPORATION, Tokyo (JP)

(72) Inventors: Yasutaka WATANABE, Itabashi-ku, Tokyo (JP); Yasunori KARASAWA, Itabashi-ku, Tokyo (JP)

(21) Appl. No.: 17/441,688

(22) PCT Filed: Mar. 17, 2020
(86) PCT No.: PCT/JP2020/011589

§ 371 Date: Sep. 21, 2021

(30) Foreign Application Priority Data
Mar. 22, 2019 (JP) 2019-055181

(51) Int. Cl. C09J 179/08; C09J 7/35; C09J 7/10; C09J 11/06; H01L 23/29

(52) U.S. Cl. CPC C09J 179/08; C09J 7/35; C09J 7/10; C08K 5/34926; H01L 23/293; C09J 2479/08; C09J 11/06

(57) ABSTRACT

A resin sheet is made of a resin composition containing a (A) heat-curable component. The (A) heat-curable component contains a (A1) first maleimide resin. The (A1) first maleimide resin is a maleimide resin having two or more maleimide groups in one molecule, at least a pair of the maleimide groups being bonded by a binding group whose main chain includes four or more methylene groups.

### TECHNICAL FIELD

The present invention relates to a resin sheet.

### BACKGROUND ART

Highly heat-resistant resin compositions are used as a sealing material for power semiconductors and the like.

For instance, Patent Literature 1 discloses a resin composition containing a maleimide compound, a compound containing at least one of an allyl group or an epoxy group, an amine compound, and a radical generator containing at least one of an acetophenone derivative or a tetraphenylethane derivative.

Additionally, studies have been made to blend maleimide resins, some of which are known to affect a dielectric property of a resin composition (i.e. to lower a dielectric loss tangent of the resin composition), into the resin composition in order to provide such an advantage.

### CITATION LIST

### Patent Literature(s)

Patent Literature 1: JP 2015-147849 A

### SUMMARY OF THE INVENTION

### Problems to be Solved by the Invention

However, the resin composition disclosed in Patent Literature 1, which exhibits improved heat resistance by the presence of the maleimide compound, disadvantageously lowers flexibility of a cured product (i.e. a cured product of a resin sheet).

An object of the invention is to provide a resin sheet whose cured product exhibits sufficient flexibility and heat resistance. Another object of the invention is to provide a resin sheet, which, while containing a maleimide resin, is capable of producing a cured product exhibiting sufficient flexibility.

### Means for Solving the Problems

A resin sheet according to an aspect of the invention is a resin sheet made of a resin composition containing a (A) heat-curable component, in which the (A) heat-curable component contains a (A1) first maleimide resin, and the (A1) first maleimide resin is a maleimide resin having two or more maleimide groups in one molecule, at least a pair of the maleimide groups being bonded by a binding group whose main chain includes four or more methylene groups,

In the resin sheet according to the above aspect of the invention, it is preferable that the (A1) first maleimide resin is a maleimide resin that is liquid at 25 degrees C.

In the resin sheet according to the above aspect of the invention, it is preferable that the (A1) first maleimide resin is represented by a formula (A1) below.

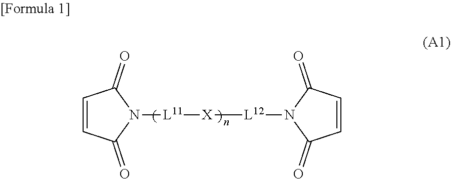

In the formula (A1): n is an integer of 0 or more; L¹¹ and L¹² are each independently a substituted or unsubstituted alkylene group having 4 or more carbon atoms, at least one of —CH₂— in the alkylene group being optionally replaced by —CH₂—O— or —O—CH₂—; and X is each independently a group not including a substituted or unsubstituted alkylene group having 4 or more carbon atoms whose at least one of —CH₂— is optionally replaced by —CH₂—O— or —O—CH₂—.

In the resin sheet according to the above aspect of the invention, it is preferable that the alkylene group in the formula (A1) is substituted by a substituent, the substituent being an alkyl group having 1 to 10 carbon atoms or an alkoxy group having 1 to 10 carbon atoms.

In the resin sheet according to the above aspect of the invention, it is preferable that the (A) heat-curable component further contains a (A2) second maleimide resin different from the (A1) first maleimide resin.

In the resin sheet according to the above aspect of the invention, it is preferable that a mass ratio (A1/A2) of the (A1) first maleimide resin to the (A2) second maleimide resin is 0.5 or more.

In the resin sheet according to the above aspect of the invention, it is preferable that a total content of the (A1) first maleimide resin and the (A2) second maleimide resin in the (A) heat-curable component is 60 mass % or more in terms of a total solid content of the (A) heat-curable component.

In the resin sheet according to the above aspect of the invention, it is preferable that the (A) heat-curable component further contains a (A3) allyl resin.

In the resin sheet according to the above aspect of the invention, it is preferable that the resin composition further contains a (B) binder component containing at least one resin selected from the group consisting of a phenoxy resin and a polyimide-imide resin.

In the resin sheet according to the above aspect of the invention, it is preferable that the resin composition further contains a triazine compound.

In the resin sheet according to the above aspect of the invention, it is preferable that the triazine compound is an imidazole compound having a triazine skeleton.

In the resin sheet according to the above aspect of the invention, it is preferable that a peel-strength after being thermally cured is 2.0 N/10 mm or more.

In the resin sheet according to the above aspect of the invention, it is preferable that the resin sheet is usable for sealing a semiconductor element, or as a component interposed between the semiconductor element and another electronic component.

In the resin sheet according to the above aspect of the invention, it is preferable that the resin sheet is usable for sealing a power semiconductor element, or as a component interposed between the power semiconductor element and another electronic component.

In the resin sheet according to the above aspect of the invention, it is preferable that the resin sheet is usable for sealing a semiconductor element made of at least one of silicon carbide or gallium nitride or as a component interposed between the semiconductor element made of at least one of silicon carbide or gallium nitride, and another electronic component.

According to the above aspect of the invention, a resin sheet whose cured product (i.e. cured resin sheet) exhibits sufficient flexibility and heat resistance can be provided. Further, a resin sheet, which, while containing a maleimide resin, is capable of providing a cured product exhibiting sufficient flexibility, can be provided.

### BRIEF DESCRIPTION OF DRAWING(S)

FIG. 1 is a schematic cross-sectional view of a laminate according to an exemplary embodiment.

### DESCRIPTION OF EMBODIMENT(S)

### Resin Composition

Initially, a resin composition for providing a resin sheet according to an exemplary embodiment will be described below.

The resin composition according to the present exemplary embodiment contains a (A) heat-curable component. The (A) heat-curable component according to the present exemplary embodiment contains a (A1) first maleimide resin.

### (A) Heat-Curable Component

The (A) heat-curable component (sometimes simply referred to as a “(A) component” hereinafter) has a property of forming a three-dimensional network upon being heated to be firmly bonded to an adherend. As described above, the (A) heat-curable component of the present exemplary embodiment contains the (A1) first maleimide resin (sometimes simply referred to as a “(A1) component” hereinafter).

### (A1) First Maleimide Resin

The (A1) first maleimide resin of the present exemplary embodiment is a maleimide resin having two or more maleimide groups in one molecule, at least a pair of the maleimide groups being bonded by a binding group whose main chain has four or more methylene groups.

In view of flexibility of the cured product, the binding group bonding the two maleimide groups herein preferably has six or more methylene groups in the main chain, more preferably eight or more methylene groups in the main chain, especially preferably ten or more methylene groups in the main chain. These methylene groups are further preferably mutually bonded to form an alkylene group having four or more carbon atoms. In this alkylene group, at least one of —CH₂— is optionally replaced with —CH₂—O— or —O—CH₂—.

Further, the binding group bonding the two maleimide groups preferably has one or more side chains in view of flexibility of the cured product. Examples of the side chains include an alkyl group and an alkoxy group. When the binding group has two or more side chains, the side chains are optionally mutually bonded to form an alicyclic structure.

The (A1) first maleimide resin of the present exemplary embodiment preferably at least contains a maleimide resin that is liquid at a temperature of 25 degrees C. Storage modulus E′ at 250 degrees C. of the cured product of the resin sheet tends to rise when the (A1) first maleimide resin contains the maleimide resin that is liquid at the temperature of 25 degrees C. For the same reason, the content of the maleimide resin that is liquid at the temperature of 25 degrees C. based on a total amount of the (A1) first maleimide resin is preferably 35 mass % or more, more preferably 65 mass % or more and 100 mass % or less.

The (A1) first maleimide resin of the present exemplary embodiment is preferably represented by a formula (A1) below in view of the flexibility and heat resistance of the cured product.

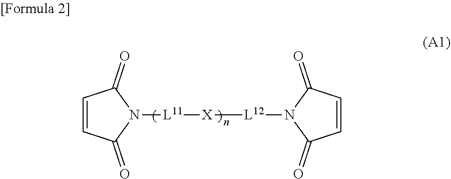

In the formula (A1), n is an integer of 0 or more, preferably an integer in a range from 1 to 10, more preferably an integer in a range from 1 to 5. Further, the average of n is preferably in a range from 0.5 to 5, more preferably in a range from 1 to 2.

L¹¹ and L¹² are each independently a substituted or unsubstituted alkylene group having 4 or more carbon atoms. In this alkylene group, at least one of —CH₂— is optionally replaced with —CH₂—O— or —O—CH₂—. In view of the flexibility of the cured product, the alkylene group preferably has 6 or more carbon atoms, more preferably 8 or more carbon atoms, especially preferably 10 to 30 carbon atoms. When a hydrogen atom of the alkylene group is replaced with a substituent, the substituent is an alkyl group having 1 to 14 carbon atoms, or an alkoxy group having 1 to 14 carbon atoms. Further, the substituents are optionally bonded to form an alicyclic structure.

X is each independently a group not having any substituted or unsubstituted alkylene group having 4 or more carbon atoms (including those whose at least one of —CH₂— is replaced with —CH₂—O— or —O—CH₂—). X is preferably a divalent group having a phthalimide group. It should be noted that the phthalimide group includes groups derived from phthalimide. Specific examples of X include groups represented by structural formulae (A1-1), (A1-2), and (A1-3) below.

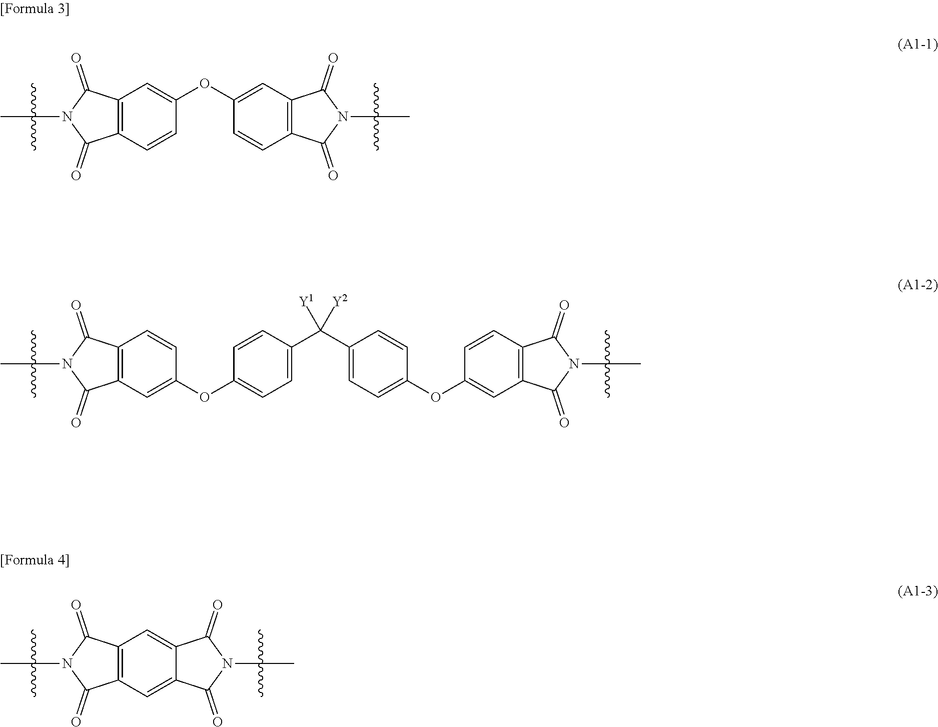

In the formula (A1-2), Y¹ and Y² are each independently a hydrogen atom, a methyl group, or an ethyl group, preferably a methyl group.

Specific examples of the maleimide resin represented by the formula (A1) according to the present exemplary embodiment include compounds represented by formulae (A1-1-1) and (A1-2-1) below. These compounds are liquid at a temperature of 25 degrees C.

Specific examples of the maleimide resin represented by the formula (A1) according to the present exemplary embodiment include a compound represented by a formula (A1-3-1) below. This compound is solid at a temperature of 25 degrees C.

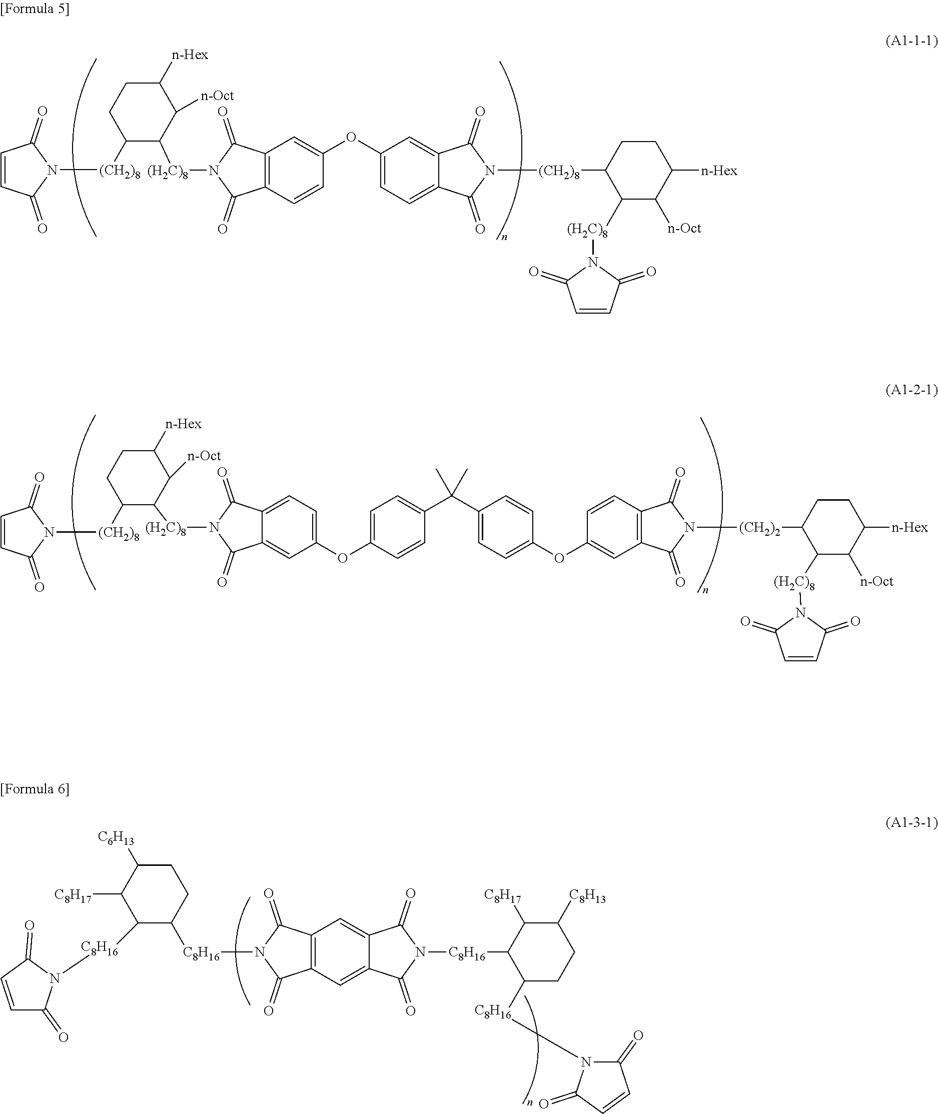

In the formulae (A1-1-1) and (A1-2-1), n is an integer in a range from 1 to 5. Further, the average of n is in a range from 1 to 2.

Examples of products of the maleimide resin represented by the formula (A1-1-1) include “BMI-1500” manufactured by Designer Molecules Inc.

Examples of products of the maleimide resin represented by the formula (A1-2-1) include “BIM-1700” manufactured by Designer Molecules inc.

In the formula (A1-3-1), n is an integer in a range from 1 to 5.

Examples of products of the maleimide resin represented by the formula (A1-3-1) include “SLK-3000” manufactured by Shin-Etsu Chemical Co., Ltd.

### (A2) Maleimide Resin

In order to increase the storage modulus E′ at 250 degrees C. of the cured product of the resin sheet, the (A) heat-curable component contained in the resin composition of the present exemplary embodiment preferably further contains a (A2) second maleimide resin different from the above-described (A1) first maleimide resin. The (A2) second maleimide resin of the present exemplary embodiment (sometimes simply referred to as a “(A2) component” hereinafter) is not specifically limited as long as the second maleimide resin is different from the (A1) first maleimide resin and contains two or more maleimide groups in one molecule.

The (A2) second maleimide resin of the present exemplary embodiment is typically solid in nature at 25 degrees C.

In view of heat resistance, the (A2) second maleimide resin of the present exemplary embodiment preferably includes, for instance, a benzene ring, more preferably a structure including a benzene ring bonded with a maleimide group. Further, the maleimide compound preferably includes two or more structures each including a benzene ring bonded with a maleimide group.

The (A2) second maleimide resin of the present exemplary embodiment is preferably a maleimide resin including two or more maleimide groups and one or more biphenyl skeletons in one molecule (sometimes simply referred to as a “biphenyl maleimide resin” hereinafter).

The (A2) second maleimide resin of the present exemplary embodiment is preferably represented by a formula (1) below in view of the heat resistance and adhesiveness.

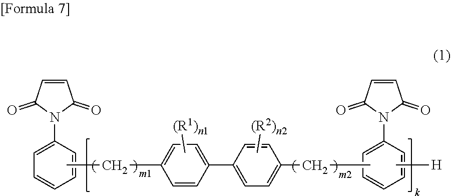

In the formula (1), k is an integer of 1 or more. The average of k is preferably in a range from 1 to 10, more preferably in a range from 1 to 5, further preferably in a range from 1 to 3. m1 and m2 are each independently an integer in a range from 1 to 2, more preferably 1. It should however be noted that the sum of m1 and m2 is 3 or less. n1 and n2 are each independently an integer in a range from 0 to 4, preferably an integer in a range from 0 to 2, more preferably 0. R¹ and R² are each independently an alkyl group having 1 to 6 carbon atoms, preferably an alkyl group having 1 to 3 carbon atoms, more preferably a methyl group. A plurality of R¹ are mutually the same or different. A plurality of R² are mutually the same or different.

Specific examples of the maleimide resin represented by the formula (1) according to the present exemplary embodiment include, for instance, a compound represented by a formula (2) or a formula (3) below.

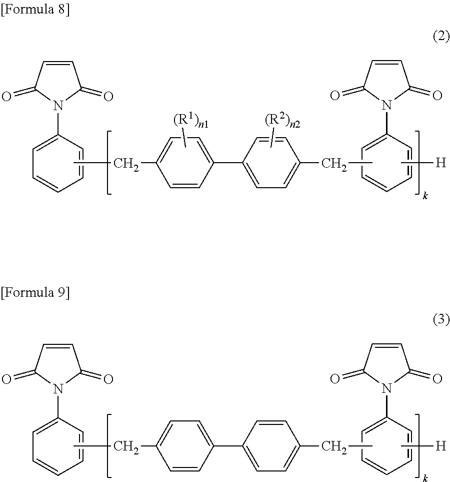

In the formulae (2) and (3), k represents the same ask in the formula (1). In the formula (2), n1, n2, R¹ and R² represent the same as n1, n2, R¹ and R² in the formula (1), respectively.

Examples of products of the maleimide resin represented by the formula (3) include “M1R-3000-70MT” manufactured by Nippon Kayaku Co., Ltd.

The (A2) second maleimide resin of the present exemplary embodiment is preferably a maleimide resin including two or more maleimide groups and two or more phenylene groups in one molecule. In order to enhance solubility to a solvent and improve sheet-formability, the phenylene group is preferably substituted by a substituent, Examples of the substituent include alkyl groups such as a methyl group and ethyl group, and alkylene groups.

In view of sheet-formability, the (A2) second maleimide resin of the present exemplary embodiment is preferably a maleimide resin having an ether bond between the maleimide group and the phenylene group.

The maleimide resin having two or more maleimide groups and two or more phenylene groups in one molecule is represented by, for instance, a formula (4) below.

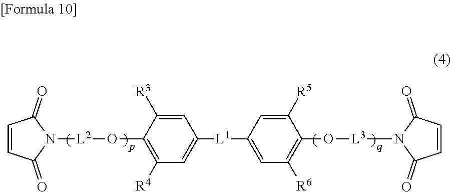

In the formula (4), R³ to R⁶ are each independently a hydrogen atom or an alkyl group having 1 to 6 carbon atoms, L¹ is an alkylene group having 1 to 3 carbon atoms, L² and L³ are each independently an alkylene group having 1 to 2 carbon atoms, or an arylene group having 6 to 10 carbon atoms, and p and q are each independently 0 or 1. It should however be noted that a sum of the carbon atoms of L¹, L² and L³ is 3 or less,

The maleimide resin represented by the formula (4) according to the present exemplary embodiment is specifically represented by, for instance, a formula (5) or a formula (6) below.

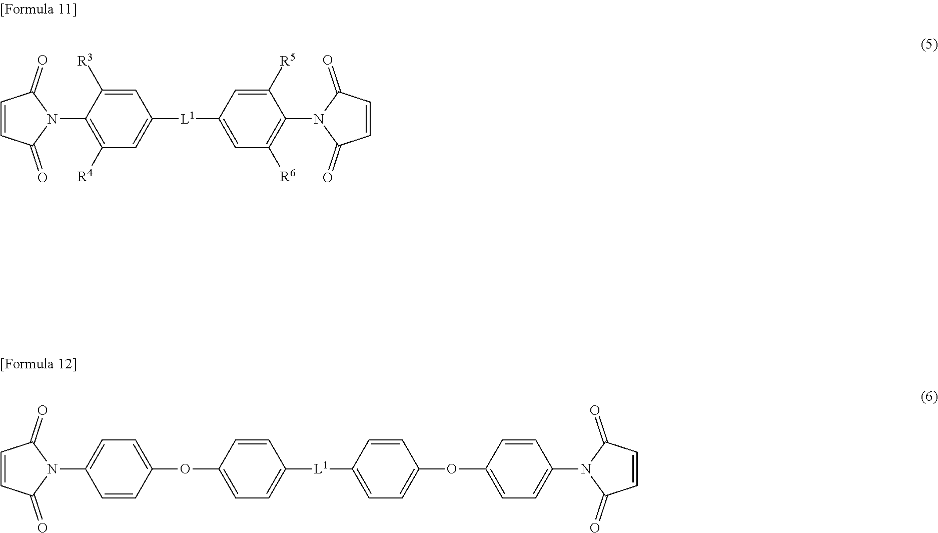

In the formulae (5) and (6), L¹ is an alkylene group having 1 to 3 carbon atoms.

In the formula (5), R³ to R⁶ are each independently a hydrogen atom or an alkyl group having 1 to 6 carbon atoms.

For instance, the (A2) second maleimide resin of the present exemplary embodiment is specifically preferably the maleimide resin represented by the formula (3), bis(3-ethyl-5-methyl-4-maleimidephenyl)methane, N,N′-1,3-phenylenedimaleimide, 4-methyl-1,3-phenylenebismaleimide, polyphenyl methane maleimide, or 2,2-bis[4-(4-maleimidephenoxy)phenyl]propane in order to obtain a cured product with sheet-formability and high heat resistance, more preferably the maleimide resin represented by the formula (3) or bis(3-ethyl-5-methyl-4-maleimidephenyl)methane in view of sheet-formability, further preferably the maleimide resin represented by the formula (3) in order to lower a high-temperature complex viscosity of pre-cured resin sheet of the present exemplary embodiment.

In the present exemplary embodiment, a mass ratio (A1/A2) of the (A1) component to the (A2) component is preferably 0.5 or more, more preferably 1 or more, especially preferably 2 or more. An upper limit of the mass ratio (A1/A2) of the (A1) component to the (A2) component is preferably 5 or less, more preferably 4 or less. The flexibility of the cured product can be further improved at the mass ratio (A1/A2) of 0.5 or more. At the mass ratio (A1/A2) of 5 or less, the storage modulus E′ of the cured product of the resin sheet at 250 degrees C. tends to increase. When the (A) heat-curable component contains a later-described (A3) allyl resin, the mass ratio (A1/A2) of the (A1) component to the (A2) component is optionally 6 or more, preferably 8 or more. When the (A) heat-curable component contains the (A3) allyl resin and the mass ratio (A1/A2) of the (A1) component to the (A2) component is 6 or more, the flexibility of the cured product can be further enhanced while the storage modulus E′ at 250 degrees C. and peel-strength of the cured product of the resin sheet are kept at high levels. In this case, an upper limit of the mass ratio (A1/A2) of the (A1) component to the (A2) component is not particularly limited, where the (A) heat-curable component optionally does not contain the (A2) component but contains only the (A1) component as the maleimide resin.

In the present exemplary embodiment, the sum of the contents of the (A1) and (A2) components in the (A) component is preferably 60 mass % or more in terms of a total solid content of the (A) component (i.e. for 100 mass % of a content of a non-volatile component of the (A) component excluding a solvent), more preferably 65 mass % or more, especially preferably 70 mass % or more. With the total content of the (A1) and (A2) components in the (A) component within the above range, the heat resistance of the cured resin sheet of the present exemplary embodiment can be improved.

### (A3) Allyl Resin

The (A) heat-curable component contained in the resin composition of the present exemplary embodiment preferably further contains a (A3) allyl resin. The (A3) allyl resin (sometimes simply referred to as a “(A3) component” hereinafter) is preferably liquid at a normal temperature. The allyl resin contained in the (A) heat-curable component further facilitates improvement in the peel-strength of the cured resin sheet of the present exemplary embodiment while lowering a reaction temperature of the resin sheet.

In the present exemplary embodiment, a mass ratio ((A1+A2)/A3) of the total content of the (A1) and (A2) components to the (A3) allyl resin of the maleimide resin is preferably 1.5 or more, more preferably 3 or more.

At the mass ratio ((A1+A2)/A3) within the above range, the storage modulus E at 250 degrees C. of the cured product of the resin sheet tends to increase.

At the mass ratio ((A1+A2)/A3) within the above range, the heat resistance of the resin sheet is also improvable.

At the mass ratio ((A1+A2)/A3) within the above range, while complex viscosity η of the resin sheet is appropriately adjusted to ensure fluidity of the resin sheet when the resin sheet is applied on an adherend, the heat resistance of the cured resin sheet can be further improved. In addition, at the mass ratio ((A1+A2)/A3) within the above range, the allyl resin is restrained from bleeding out of the resin sheet. It should be noted that the upper limit of the mass ratio ((A1+A2)/A3) is not specifically limited. For instance, the mass ratio ((A1+A2)/A3) is optionally 50 or less, preferably 15 or less.

The (A3) allyl resin of the present exemplary embodiment is not specifically limited as long as the (A3) resin includes an allyl group. For instance, the (A3) allyl resin of the present exemplary embodiment is preferably an allyl resin including two or more allyl groups in one molecule.

The allyl resin of the present exemplary embodiment is more preferably represented by a formula (7), a formula (8) or a formula (9) below.

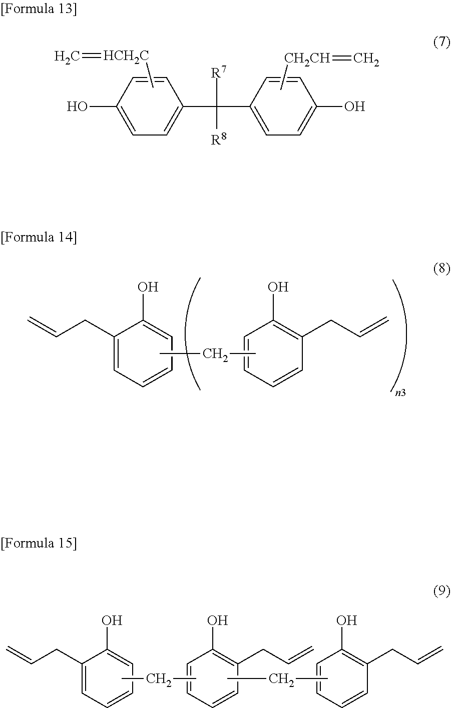

In the formula (7), R⁷ and R⁸ are each independently an alkyl group, preferably an alkyl group having 1 to 10 carbon atoms, more preferably an alkyl group having 1 to 4 carbon atoms, further preferably an alkyl group selected from the group consisting of a methyl group and an ethyl group.

In the formula (8), n3 is in a range from 1 to 4, preferably in a range from 1 to 3, more preferably in a range from 1 to 2. Further, in the allyl resin represented by the formula (8), a ratio of components whose n3 is 1 is preferably 90 mol % or more.

Specific examples of the (A3) allyl resin of the present exemplary embodiment include diallyl bisphenol A (2,2-bis(3-allyl-4-hydroxyphenyl)propane), allylphenol resins represented by the formula (8), and allylphenol resins represented by the formula (9). One type of these allyl resins is usable alone or two or more types of these allyl resins are usable in combination.

### (A4) Curing Catalyst

In the resin sheet according to the present exemplary embodiment, when the resin composition contains a heat-curable resin, the resin composition preferably further contains a curing catalyst. The curing reaction of the heat-curable resin can thus be effectively progressed, allowing efficient curing of the resin sheet. Examples of the curing catalyst include imidazole curing catalyst, amine curing catalyst, and phosphorus curing catalyst.

Specific examples of the imidazole curing catalyst include 2-methylimidazole, 2-undecylimidazole, 2-heptadecylimidazole, 2-ethyl-4-methylimidazole, 1-benzyl-2-methylimidazole, 2-phenylimidazole, 2-phenyl-4-methylimidazole, 1-benzyl-2-phenylimidazole, 1,2-dimethylimidazole, 1-cyanoethyl-2-methylimidazole, 1-cyanoethyl-2-ethyl-4-methylimidazole, 1-cyanoethyl-2-undecylimidazole, 1-cyanoethyl-2-phenylimidazole, 2-phenyl-4-methyl-5-hydroxymethylimidazole, and 2-phenyl-4,5-di(hydroxymethyl)imidazole. In view of reactivity, the use of 2-ethyl-4-methylimidazole is preferable. It should be noted that an imidazole compound having triazine skeleton, which is used as a later-described adhesion-imparting agent, also serves as the curing catalyst.

Specific examples of the amine curing catalyst include tertiary amine compounds such as 1,8-diazabicyclo[5,4,0]undecene-7 (DBU), triethylenediamine, benzyldimethylamine, and triethanolamine.

Specific examples of the phosphorus curing catalyst include phosphines such as triphenyl phosphine, tributyl phosphine, trip-methylphenyl)phosphine, and tri(nonylphenyl)phosphine.

The (A) heat-curable component of the present exemplary embodiment optionally contains a heat-curable resin other than the (A1) and (A2) components and a curable resin other than the (A3) component as long as an object of the invention is not impaired. Further, the (A) heat-curable component of the present exemplary embodiment optionally contains a (A4) curing catalyst other than the imidazole curing catalyst, amine curing catalyst, and phosphorus curing catalyst.

The heat-curable resin other than the (A1) and (A2) components is any heat-curable resin having high heat resistance, examples of which include epoxy resin, benzoxazine resin, cyanate resin, and melamine resin. One type of these heat-curable resins is usable alone or two or more types of these heat-curable resins are usable in combination.

Examples of the curable resin other than the (A3) component include resins (e.g. phenol resin and a resin having C═C double bond other than the (A3) component), acid anhydride, and formaldehyde. One type of these curable resins is usable alone or two or more types of these curable resins are usable in combination.

Examples of the (A4) curing catalyst other than the imidazole curing catalyst, amine curing catalyst, and phosphorus curing catalyst include triazole compound and thiazole compound. One type of these curing catalysts is usable alone, or two or more types of these curing catalysts are usable in combination.

When at least one of the heat-curable resin other than the (A1) component and the (A2) component or the curable resin other than the (A3) component is used, a total content of these components is preferably 10 mass % or less in terms of the total solid content of the (A) component (i.e. for 100 mass % of a content of a non-volatile component of the (A) component excluding a solvent), more preferably 5 mass % or less.

In the present exemplary embodiment, the content of the (A) heat-curable component in the resin composition is preferably in a range from 2 mass % to 75 mass % in terms of the total solid content of the resin composition (i.e. for 100 mass % of a total content of a non-volatile component of the resin composition excluding a solvent), more preferably in a range from 5 mass % to 60 mass %, especially preferably in a range from 10 mass % to 40 mass %. At the content of the (A) heat-curable component within the above range, handleability, sheet-shape retainability, and heat resistance of the resin sheet are improved.

### (B) Binder Component

In the present exemplary embodiment, the resin composition preferably contains a (B) binder component (sometimes simply referred to as a “(B) component” hereinafter) in addition to the (A) component. The (B) binder component, which is further contained in the resin composition of the present exemplary embodiment, provides film formability for the resin composition to be easily formed into a sheet shape.

The (B) binder component of the present exemplary embodiment, which is a resin component other than the (A) component, serves as a binder for the (A) component and/or other component(s). The (B) binder component is preferably a thermoplastic resin or the like. The (B) component, which is only necessary to serve as a binder for the (A) component and/or other component(s), optionally includes a functional group. The (B) binder component thus including a functional group, which may be involved in curing the resin sheet by heat, is distinguished from the (A) heat-curable component in the invention.

The (B) binder component can be selected from a wide variety of compounds (e.g. irrespective of whether the binder component is an aliphatic compound or an aromatic compound). The (B) binder component is preferably at least one resin selected from the group consisting of, for instance, phenoxy resin, acrylic resin, methacrylic resin, polyester resin, urethane resin, polyimide resin, and polyamide-imide resin, more preferably at least one resin selected from the group consisting of phenoxy resin and polyamide-imide resin in view of heat resistance. It should be noted that the polyester resin is preferably a wholly aromatic polyester resin. When the resin composition contains a later-described triazine compound, the (B) binder component is preferably a nitrogen-atom-containing resin in order to improve peel-strength of cured resin sheet by an interaction between the nitrogen-atom-containing compounds. Examples of the nitrogen-atom-containing resin include a urethane resin, polyimide resin, and polyamide-imide resin. Preferably, the nitrogen-atom-containing resin is a polyimide-imide resin. In order to improve flexibility of cured product of the resin sheet, polyimide-imide resin is preferably rubber-modified polyamide-imide resin. One type of the (B) binder component is usable alone, or two or more types of the (B) binder components are usable in combination.

The phenoxy resin is preferably a phenoxy resin having at least one skeleton selected from the group consisting of bisphenol A skeleton (bisphenol A will be sometimes referred to as “BisA” hereinafter), bisphenol F skeleton (bisphenol F will be sometimes referred to as “BisF” hereinafter), biphenyl skeleton, and naphthalene skeleton, more preferably a phenoxy resin having a bisphenol A skeleton and bisphenol F skeleton.

In order to allow easy adjustment of the complex viscosity of the resin sheet within a desired range, the weight average molecular weight (Mw) of the (B) binder component is preferably in a range from 10000 to 1000000, more preferably in a range from 30000 to 800000, further preferably in a range from 50000 to 100000. The weight average molecular weight herein refers to a standard polystyrene equivalent measured by GPC (Gel Permeation Chromatography).

The glass transition temperature (Tg) of the (B) binder component is preferably 90 degrees C. or more, more preferably 100 degrees C. or more. At the glass transition temperature (Tg) of the (B) binder component within the above range, agreeability of the cured resin sheet is improved and peel-strength can be easily increased.

In the present exemplary embodiment, the content of the (B) binder component in the resin composition is preferably in a range from 1.5 mass % to 50 mass % in terms of the total solid content of the resin composition (i.e. for 100 mass % of a total content of a non-volatile component of the resin composition excluding a solvent), more preferably in a range from 2 mass % to 30 mass %, especially preferably in a range from 2 mass % to 15 mass %. At the content of the (B) binder component in the resin composition within the above range, the complex viscosity of the pre-cured resin sheet is easily adjustable to a desired range, thereby enhancing handleability and sheet-formability of the resin sheet.

### (C) Inorganic Filler

In the present exemplary embodiment, the resin composition preferably contains a (C) inorganic filler (sometimes simply referred to as a “(C) component” hereinafter) in addition to the (A) component and (B) component. At least one of heat characteristics or mechanical characteristics of the resin sheet can be improved by the (C) component.

Examples of the (C) inorganic filler include silica filler, alumina filler, and boron nitride filler. Among the above, silica filler is preferable.

Examples of the silica filler include molten silica and spherical silica.

One type of the (C) inorganic filler is usable alone or two or more types of the inorganic fillers are usable in combination. The (C) inorganic filler is optionally surface-treated,

An average particle size of the (C) inorganic filler is not specifically limited. The average particle size of the (C) inorganic filler, which is a value measured using a typical particle size distribution analyzer, is preferably in a range from 0.1 nm to 100 μm, more preferably in a range from 10 nm to 10 μm. The average particle size of the (C) inorganic filler herein is a value measured through dynamic light scattering using a particle size distribution analyzer (product name “Nanotrac Wave-UT151” manufactured by Nikkiso Co., Ltd.).

The content of the (C) inorganic filler in the resin composition is preferably in a range from 10 mass % to 90 mass % in terms of the total solid content of the resin composition (i.e. for 100 mass % of a total content of a non-volatile component of the resin composition excluding a solvent), more preferably in a range from 20 mass % to 85 mass %, further preferably in a range from 40 mass % to 80 mass %, especially preferably in a range from 60 mass % to 80 mass %. At the content of the (C) inorganic filler in the resin composition within the above range, the linear expansion coefficient of the resin sheet can be lowered to reduce, for instance, a difference between a linear expansion coefficient of a to-be-sealed object (e.g. silicon carbide) and a linear expansion coefficient of the resin sheet.

### (D) Coupling Agent

In the present exemplary embodiment, the resin composition preferably further contains a (D) coupling agent in addition to the (A) to (C) components.

The coupling agent preferably includes a group reactive with a functional group of a compound contained in the above-described (A) heat-curable component or a functional group included in the (B) binder component, more preferably includes a group reactive with a functional group of a compound contained in the above-described (A) heat-curable component.

The use of the (D) coupling agent improves peel-strength between a cured product of the resin sheet and an adherend.

The (D) coupling agent is preferably a silane coupling agent in view of versatility and cost advantage thereof. One type of the (0) coupling agent is usable alone or two or more types of the (D) coupling agents are usable in combination. The above coupling agent is blended in an amount ranging from 0.1 parts by mass to 20 parts by mass for 100 parts by mass of the (A) heat-curable component, preferably in a range from 0.3 parts by mass to 15 parts by mass, more preferably in a range from 0.5 parts by mass to 10 parts by mass.

### Adhesion-Imparting Agent

In the present exemplary embodiment, the resin composition preferably further contains an adhesion-imparting agent in addition to the (A) to (D) components.

Examples of the adhesion-imparting agent include a triazine compound. The triazine compound is optionally an imidazole compound having a triazine skeleton.

Examples of the imidazole compound having a triazine skeleton includes a compound represented by a formula (10) below.

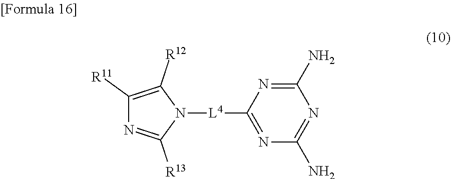

In the formula (10), R¹¹ and R¹² are each independently a hydrogen atom, an alkyl group having 1 to 20 carbon atoms, a hydroxymethyl group, or a phenyl group, preferably a hydrogen atom or an alkyl group having 1 to 10 carbon atoms, more preferably a hydrogen atom or an alkyl group having 1 to 3 carbon atoms. R¹³ is a hydrogen atom, an alkyl group having 1 to 20 carbon atoms, a phenyl group, or an allyl group, preferably an alkyl group having 1 to 10 carbon atoms, more preferably an alkyl group having 1 to 3 carbon atoms. L⁴ is an alkylene group having 1 to 5 carbon atoms, preferably an alkylene group having 2 to 4 carbon atoms, more preferably an ethylene group.

Specific examples of the imidazole compound having a triazine skeleton of the present exemplary embodiment include 2,4-diamino-6-[2-(2-methyl-1-imidazolyl)ethyl]-1,3,5-triazine, 2,4-diamino-6-[2-(2-ethyl-4-methyl-1-imidazolyl)ethyl]-1,3,5-triazine, and 2,4-diamino-6-[2-(2-undecyl-1-imidazolyl)ethyl]-1,3,5-triazine. Among the above compounds, in view of peel-strength and reaction temperature of the resin sheet, 2,4-diamino-6-[2-(2-methyl-1-imidazolyl)ethyl]-1,3,5-triazine, or 2,4-diamino-6-[2-(2-ethyl-4-methyl-1-imidazolyl)ethyl]-1,3,5-triazine is preferable.

In the present exemplary embodiment, the content of the adhesion-imparting agent in the resin composition is preferably in a range from 0.05 mass % to 3 mass % in terms of the total solid content of the resin composition (i.e. for 100 mass % of a total content of a non-volatile component of the resin composition excluding a solvent), more preferably in a range from 0.1 mass % to 2 mass %. At the content of the adhesion-imparting agent within the above range, the peel-strength of the cured resin sheet is further improvable.

Examples of the resin composition of the present exemplary embodiment include a resin composition consisting of the (A), (B), and (C) components, a resin composition consisting of the (A), (B), (C), and (D) components, and a resin composition consisting of the (A), (B), (C), and (D) components, and adhesion-imparting agent.

Another example of the resin composition of the present exemplary embodiment is a resin composition containing the (A), (B), (C), and (D) components, adhesion-imparting agent, and a component(s) other than the (A), (B), (C), and (D) components and adhesion-imparting agent, as described later.

### Other Components

The resin composition of the present exemplary embodiment optionally further contains other components. Examples of the other components include at least one component selected from the group consisting of a cross-linker, pigment, dye, antifoaming agent, leveling agent, ultraviolet absorber, foaming agent, antioxidant, flame retardant, and ion scavenger.

For instance, the resin composition optionally further contains a cross-linker in order to adjust primary adhesivity and aggregability of the pre-cured resin sheet.

Examples of the cross-linker include an organic polyvalent isocyanate compound, and an amino resin. One type of the cross-linker is usable alone or two or more types of the cross-linker are usable in combination.

Examples of the organic polyvalent isocyanate compound include aromatic polyvalent isocyanate compound, aliphatic polyvalent isocyanate compound, alicyclic polyvalent isocyanate compound, trimers of these polyvalent isocyanate compounds, and isocyanate-terminated urethane prepolymer obtained through a reaction of one or more of these polyvalent isocyanate compounds and a polyol compound.

Further specific examples of the organic polyvalent isocyanate compound include 2,4-tolylene diisocyanate, 2,6-tolylene diisocyanate, 1,3-xylylene diisocyanate, 1,4-xylene diisocyanate, diphenylmethane-4,4′-diisocyanate, diphenylmethane-2,4′-diisocyanate, 3-methyldiphenylmethane diisocyanate, hexamethylene diisocyanate, isophorone diisocyanate, dicyclohexylmethane-4,4′-diisocyanate, dicyclohexylmethane-2,4′-diisocyanate, and lysine isocyanate. One type of the organic polyvalent isocyanate compound is usable alone, or two or more types of the organic polyvalent isocyanate compounds are usable in combination.

Examples of the usable amino resin include urea resin, melamine resin, guanamine resin, and cocondensated resin of these resins.

The above cross-linker is typically blended in an amount ranging from 0.01 parts by mass to 12 parts by mass for 100 parts by mass of the above-described (B) binder component, preferably in a range from 0.1 parts by mass to 10 parts by mass.

In the present exemplary embodiment, the resin composition preferably contains a solvent when the resin sheet is to be formed through a coating process. Examples of the solvent include typical solvents such as toluene, ethyl acetate, and methylethylketone, and high-boiling solvents such as cyclohexanone (boiling point: 155.6 degrees C.), dimethyl formamide (boiling point: 153 degrees C.), dimethyl sulfoxide (boiling point: 189.0 degrees C.), ethers of ethylene glycol (cellosolve) (boiling point: approximately 120 to 310 degrees C.), and ortho-xylene (boiling point: 144.4 degrees C.).

### Resin Sheet

The resin sheet of the present exemplary embodiment is made of the above-described resin composition of the present exemplary embodiment. The resin sheet of the present exemplary embodiment can further improve flexibility while keeping heat resistance.

In view of sealability for semiconductor element or, conformability to surface irregularities of an adherend to be adhered when the resin sheet is interposed between the semiconductor element and other electronic components, the resin sheet preferably consists of the resin composition according to the present exemplary embodiment. In other words, the resin sheet is preferably not, for instance, a composite material produced by combining the resin composition and a fiber sheet (e.g. a prepreg).

The peel-strength of the thermally cured resin sheet of the present exemplary embodiment is preferably 2.0 N/10 mm or more, more preferably in a range from 3.0 N/10 mm to 50 N/10 mm, further preferably in a range from 4.0 N/10 mm to 40 N/10 mm.

When the peel-strength of the thermally cured resin sheet of the present exemplary embodiment is 2.0 N/10 mm or more, high adhesivity to an adherend can be maintained when the resin sheet is used as a sealing material.

The peel-strength of the thermally cured resin sheet of the present exemplary embodiment can be adjusted within the above range by, for instance, selecting the components to be used for the resin composition, preferably blending at least one type selected from the allyl resin and the adhesion-imparting agent, and adjusting the type and blending amount of the allyl resin and/or the adhesion-imparting agent. In addition, the peel-strength of the cured resin sheet can be adjusted to the above range by, for instance, preferably selecting a binder component with a high glass transition temperature and blending the binder component to the resin composition. Further, the peel-strength of the cured resin sheet also can be adjusted to the above range by selecting the nitrogen-atom-containing resin as the binder component, and blending the triazine compound to the resin composition.

It should be noted that the peel-strength of the thermally cured resin sheet of the present exemplary embodiment was measured through a below-described measurement method, where a peeling test was performed between a thermally cured resin sheet and an adherend at a peel angle of 90 degrees. Specifically, a test piece, which was prepared as described below, was subjected to a peeling test.

### (i) Preparation Method of Test Piece

Adherend: copper foil (size 50 mm×10 mm, 150 μm thick, as specified by JIS H 3100)

Laminator: “V-130” manufactured by Nikko-Materials Co., Ltd.

Pressure bonding conditions: lamination temperature 130 degrees C., reached pressure 100 Pa, time 60 seconds

Heat-curing conditions of resin sheet: thermal curing temperature 200 degrees C., thermal curing time 4 hours

Thermal history test conditions: temperature 200 degrees C., test time 1000 hours

### (ii) Peeling Test Method

Used machine: tensile tester (“Autograph AG-100NX plus” manufactured by Shimadzu Corporation)

Peeling method: peel an adherend from a cured resin sheet

Peeling rate: 50 mm/min

Peel angle: 90 degrees

Measurement environment: 23 degrees C., under 50% relative humidity environment

The resin sheet of the present exemplary embodiment, which is a sheet-shaped component of the resin composition, is easily applicable to an adherend, especially to an adherend of a large area.

The sheet-shaped resin composition, which is formed in advance in a shape suitable for the shape after a sealing step, can be supplied in a form of a sealing material with a certain uniformity only by an application process. Further, the sheet-shaped resin composition, which is not fluid, is excellent in handleability,

In order to improve the heat resistance of a cured product of the resin sheet, the storage modulus E′ of the thermally cured resin sheet of the present exemplary embodiment at 250 degrees C. is preferably 150 MPa or more, more preferably 300 MPa or more, further preferably 500 MPa or more. The storage modulus E′ of the thermally cured resin sheet at 250 degrees C. is a value measured for a test piece obtained by curing the resin sheet at 200 degrees C. for four hours.

The process for shaping the resin composition into a sheet, which may be any typically known sheet-shaping process, is not specifically limited. The resin sheet of the present exemplary embodiment, which is optionally band-shaped, is optionally provided in a form of a roll of the wound sheet. The resin sheet of the present exemplary embodiment, which is in the form of the wound roll, is usable, for instance, by being unwound from the roll and cut into a desired size.

The thickness of the resin sheet of the present exemplary embodiment is, for instance, preferably 10 μm or more, more preferably 20 μm or more. Further, the thickness is preferably 500 μm or less, more preferably 400 μm or less, further preferably 300 μm or less.

The resin sheet of the present exemplary embodiment is preferably used for a semiconductor element. Specifically, the resin sheet of the present exemplary embodiment is preferably used for sealing a semiconductor element. Further, the resin sheet of the present exemplary embodiment is preferably interposed between a semiconductor element and other electronic components in use.

The semiconductor element is preferably a power semiconductor element.

The resin sheet of the present exemplary embodiment, which is excellent in heat resistance, is usable for sealing a power semiconductor element expected to be operated at a high temperature (i.e. 200 degrees C. or more), or as a component interposed between a power semiconductor element and other electronic components.

The resin sheet of the present exemplary embodiment is preferably collectively used for a plurality of semiconductor elements. For instance, the sheet-shaped resin composition is usable for a so-called “panel level package,” where the resin sheet is applied on a structure having a frame defining a plurality of cavities and semiconductor elements placed in respective cavities, thereby collectively sealing the frame and the semiconductor elements.

The resin sheet of the present exemplary embodiment is preferably used for sealing a semiconductor element made of at least one of silicon carbide or gallium nitride. Alternatively, the resin sheet of the present exemplary embodiment is preferably used as a component interposed between a semiconductor element made of at least one of silicon carbide or gallium nitride, and other electronic components. Examples of other electronic components include a printed wiring board and a lead frame.

An upper limit of the operable temperature of a silicon semiconductor element is approximately 175 degrees C. Accordingly, the power semiconductor element is preferably a semiconductor element made of at least one of silicon carbide or gallium nitride capable of high-temperature operation.

The resin sheet of the present exemplary embodiment, which is excellent in heat resistance, is usable for sealing a semiconductor element made of at least one of silicon carbide or gallium nitride that is expected to be operated at a high temperature (i.e. 200 degrees C. or more), or as a component interposed between a semiconductor element made of at least one of silicon carbide or gallium nitride, and other electronic component(s).

### Heat-Curing Conditions

In the heat-curing conditions for the resin sheet of the present exemplary embodiment, heating temperature is preferably in a range from 50 degrees C. to 220 degrees C., more preferably in a range from 100 degrees C. to 200 degrees C.

In the heat-curing conditions for the resin sheet of the present exemplary embodiment, heating time is preferably in a range from 30 minutes to 7 hours, more preferably in a range from an hour to 5 hours.

The heat-curing conditions of the resin sheet within the above ranges allow efficient thermal curing of the resin sheet.

### Laminate

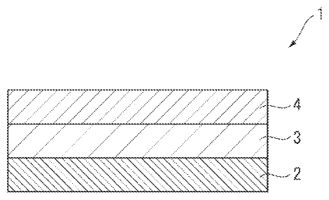

FIG. 1 is a schematic cross-sectional view of a laminate 1 according to the present exemplary embodiment.

The laminate 1 of the present exemplary embodiment includes a first release member 2, a second release member 4, and a resin sheet 3 interposed between the first release member 2 and the second release member 4. The resin sheet 3 is the resin sheet according to the present exemplary embodiment.

The first release member 2 and the second release member 4 have releasability. It is preferable that a release force of the first release member 2 with the resin sheet 3 is different from a release force of the second release member 4 with the resin sheet 3. The materials of the first release member 2 and the second release member 4 are not specifically limited. A ratio (P2/P1) of a release force P2 of the second release member 4 to a release force P1 of the first release member 2 is preferably 0.02≤P2/P1<1 or 1<P2/P1≤50.

The first release member 2 and the second release member 4 are optionally, for instance, members made of a release material that inherently has releasability, members having been subjected to a process for providing releasability, members provided by laminating release agent layers, or the like. When the first release member 2 and the second release member 4 are not subjected to the process for providing releasability, examples of the material for the first release member 2 and the second release member 4 include, for instance, olefin resin and fluorine resin.

The first release member 2 and the second release member 4 are optionally release members each provided with a release base material and a release agent layer that is provided by applying a release agent on the release base material. The release member provided with the release base material and the release agent layer is easily handleable. The first release member 2 and the second release member 4 are optionally provided with the release agent layer only on one side of the release base material or provided with the release agent layers on both sides of the release base material.

Examples of the release base material include a paper base material, a laminated paper provided by laminating a thermoplastic resin (e.g., polyethylene) on the paper base material, and a plastic film. Examples of the paper base material include glassine paper, coated paper, and cast coated paper. Examples of the plastic film include polyester film (e.g. polyethylene terephthalate, polybutylene terephthalate, and polyethylene naphthalate) and polyolefin film (e.g. polypropylene and polyethylene). Among the above, polyester film is preferable.

Examples of the release agent include silicone release agent containing silicone resin; a long-chain-alkyl-group-containing compound release agent containing a compound including a long-chain alkyl group such as polyvinyl carbamate and alkyl urea derivative; an alkyd resin release agent containing alkyd resin (e.g. non-convertible alkyd resin and convertible alkyd resin); an olefin-resin release agent containing an olefin resin (e.g. polyethylene (such as high-density polyethylene, low-density polyethylene, and linear low-density polyethylene), and crystalline polypropylene resin such as propylene homopolymer having isotactic or syndiotactic structure and propylene-α-olefin copolymer); rubber release agent containing a rubber such as a natural rubber and a synthetic rubber (e.g. butadiene rubber, isoprene rubber, styrene-butadiene rubber, methyl methacrylate-butadiene rubber, and acrylonitrile-butadiene rubber); and an acrylic-resin release agent containing an acrylic resin such as (meth)acrylic ester copolymer. One of the release agents is usable alone or two or more of the release agents are usable in combination. Among the above, alkyd resin release agent is preferable. Especially, when a phenoxy resin or a polyamide-imide resin is used as the (B) binder component of the resin composition contained in the resin sheet 3, a use of a typical silicone release agent results in unexpected peeling of the release member before the resin sheet 3 is used. Accordingly, the use of the alkyd resin release agent is preferable.

The thickness of each of the first release member 2 and the second release member 4 is not specifically limited. The thickness is typically in a range from 1 μm to 500 μm, preferably in a range from 3 μm to 100 μm.

The thickness of the release agent layer is not specifically limited. When the release agent layer is formed by applying a solution containing a release agent, the thickness of the release agent layer is preferably in a range from 0.01 μm to 3 μm, more preferably in a range from 0.03 μm to 1 μm.

A manufacturing method of the laminate 1 is not specifically limited. For instance, the laminate 1 is manufactured according to the following steps. Initially, a resin composition containing a solvent is applied on the first release member 2 to form a coating film. Subsequently, the coating film is dried to form the resin sheet 3. Subsequently, the resin sheet 3 and the second release member 4 are adhered at a normal temperature to produce the laminate 1. It should be noted that the ratio (P2/P1) of the release force P2 of the second release member 4 to the release force P1 of the first release member 2 is likely to be P2/P1<1 when the first release member 2 and the second release member 4 are of the same type. Even when the first release member 2 and the second release member 4 are of different types, the value of P2/P1 tends to become small due to the resin composition applied on the first release member 2.

### Advantage(s) of Exemplary Embodiment

The resin sheet and the laminate of the present exemplary embodiment can provide a resin sheet having sufficient flexibility and heat resistance after being cured.

As described above, the resin sheet of the present exemplary embodiment is suitably usable for a power semiconductor element. In other words, in a semiconductor device of the present exemplary embodiment, the semiconductor element is preferably a power semiconductor element. The power semiconductor element is expected to be operated at a high temperature of 200 degrees C. or more. The material used for a semiconductor device including a power semiconductor element is required to have heat resistance. The resin sheet of the present exemplary embodiment, which is excellent in heat resistance, is suitably usable for covering a power semiconductor element in the semiconductor device or as a component interposed between the power semiconductor element and other electric component(s).

As described above, the resin sheet of the present exemplary embodiment is suitably usable for a semiconductor element made of at least one of silicon carbide or gallium nitride. In other words, in a semiconductor device of the present exemplary embodiment, the semiconductor element is preferably a semiconductor element made of at least one of silicon carbide or gallium nitride. The semiconductor element made of at least one of silicon carbide or gallium nitride, whose properties are different from those of the silicon semiconductor element, is suitably usable for applications such as a power semiconductor element, a high-power device for a base station, a sensor, a detector, and Schottky barrier diode. In such applications that focus on the heat resistance of the semiconductor element made of at least one of silicon carbide or gallium nitride, the resin sheet of the present exemplary embodiment, which is excellent in heat resistance, is suitably usable in combination with the semiconductor element made of at least one of silicon carbide or gallium nitride.

### Modification of Exemplary Embodiment

The invention is not limited to the above-described exemplary embodiment but includes modifications and improvements as long as such modifications and improvements are compatible with an object of the invention.

The laminate, which is described to include the first release member, the second release member, and the resin sheet provided between the first release member and the second release member in the exemplary embodiment, has the release member only on one side of the resin sheet in some embodiments.

The resin sheet of the invention, which is described to be used for sealing a semiconductor in the exemplary embodiment directed to the semiconductor device, is additionally usable as an insulating material for a circuit board (e.g. a hard printed wiring board material, a flexible wiring board material, and a build-up board interlayer insulating material), a build-up adhesive film, an adhesive and the like.

### EXAMPLES

The invention will be described below in more detail with reference to Examples. It should however be noted that the scope of the invention is by no means limited by the Examples.

### Preparation of Resin Composition

Resin compositions according to Examples 1 to 7 and Comparatives 1 and 2 were prepared in accordance with blend ratios (mass % (ratio in terms of solid content)) shown in Table 1.

The materials used for preparing the resin composition were as follows.

### Heat-Curable Component

First maleimide resin-1: a long-chain alkyl maleimide resin (the maleimide resin represented by the formula (A1-1-1), “BMI-1500” manufactured by Designer Molecules Inc.)

First maleimide resin-2: a long-chain alkyl maleimide resin (the maleimide resin represented by the formula (A1-2-1), “BMI-1700” manufactured by Designer Molecules Inc.)

First maleimide resin-3: a long-chain alkyl maleimide resin (the maleimide resin represented by the formula (A1-3-1), “SLK-3000” manufactured by Shin-Etsu Chemical Co., Ltd.)

Second maleimide resin: a maleimide resin having a biphenyl group (the maleimide resin represented by the formula (3), “MIR-3000-70MT” manufactured by Nippon Kayaku Co., Ltd.)

Allyl resin: diallyl bisphenol A (“DABPA” manufactured by Daiwa Kasei Industry Co., Ltd.)

Curing catalyst: 2-ethyl-4-methylimidazole

Epoxy resin: biphenyl epoxy resin (“NC3000H” manufactured by Nippon Kayaku Co., Ltd.)

Phenol resin: biphenyl phenol novolac resin (“MEH-7851-H” manufactured by MEIWA PLASTIC INDUSTRIES, LTD.)

### Binder Component

Binder resin-1: BisA/BisF mixed phenoxy resin (“ZX-1356-2” manufactured by Nippon Steel & Sumikin Chemical Co., Ltd., weight average molecular weight 65,000, glass transition temperature: 72 degrees C.)

Binder resin-2: BisA phenoxy resin (“YX7200B35” manufactured by Mitsubishi Chemical Corporation, glass transition temperature: 150 degrees C.)

Binder resin-3: rubber-modified polyamideimide (“BPAM01H” manufactured by Nippon Kayaku Co., Ltd., glass transition temperature: −43.4 degrees C.)

### Inorganic Filler

Silica filler: molten silica (epoxy-silane modified, average particle size 0.5 μm, maximum particle size 2.0 μm)

### Coupling Agent

Silane coupling agent: 3-glycidoxypropyl triethoxysilane

### Adhesion-Imparting Agent

Adhesion-imparting agent: 2,4-diamino-6-[2-(2-ethyl-4-methyl-1-midazolyl)ethyl]-1,3,5-triazine (“2E4MZ-A” manufactured by SHIKOKU CHEMICALS CORPORATION)

### Evaluation of Thermally Cured Resin Sheet

### Preparation of Laminate Including Resin Sheet

Resin varnish (coating solution prepared by dissolving the resin composition in a mixture solvent of cyclohexanone and methylethyl ketone, whose solid content concentration was 60 mass %) was applied on the first release member (polyethylene terephthalate film provided with a release layer made of an alkyd resin release agent, “PET38AL-5” manufactured by LINTEC Corporation, thickness 38 μm) using a knife coater, and was dried for two minutes at 100 degrees C. The thickness of the dried resin composition was 25 μm. Immediately after the first release member was taken out of a drying furnace, the dried resin composition and the second release member (polyethylene terephthalate film provided with a release layer made of a silicone release agent, “SP-PET382150” manufactured by LINTEC Corporation, thickness 38 μm) were adhered at a normal temperature to prepare a laminate with the first release member, the resin sheet made of the resin composition, and the second release member being laminated in this order.

### Evaluation of Flexibility of Cured Product (Three-Point Bending Test)

The resultant resin composition was applied on the release member and was dried at 90 degrees C. for one minute and at 110 degrees C. for one minute to prepare a 25-μm-thick resin sheet. Eight pieces of the resin sheet were laminated to produce a 200-μm-thick sheet, which was subsequently released from the release member to prepare a sample. After the sample was cured under heat-curing conditions (at 200 degrees C. for four hours), the sample was cut into thermally cured products of the resin sheet (size: 20 mm×10 mm) to prepare test pieces for evaluating flexibility. Using a tensile tester (“Autograph AG-IS” manufactured by Shimadzu Corporation), wedge-shaped jig was lowered under the conditions below from above the center of the test piece horizontally placed on two supporting points to perform the three-point bending test, where displacement of the test piece when the test piece was torn apart was measured (jig pushing amount, unit: mm). The obtained results are shown in Table 1. It should be noted that larger displacement shows more excellent flexibility. Distance between supporting points: 6 mm Jig lowering rate: 0.5 mm/min

### Measurement of Elastic Modulus at 250 Degrees C.

The same sample as used in evaluating the flexibility of the cured product was cured under the heat-curing conditions (at 200 degrees C. for four hours) to prepare a measurement sample. The storage modulus E′ (unit: MPa) of the measurement sample at 250 degrees C. was measured under conditions of temperature-rise rate of 3 degrees min, temperature range of 30 to 300 degrees C., and frequency of 11 Hz using “DMA 0800” manufactured by TA Instruments, Inc. The obtained results are shown in Table 1. It should be noted that larger storage modulus at 250 degrees C. shows more excellent heat resistance.

### Measurement of Peel-Strength

A 6-inch Si wafer was cut in advance into quarters to prepare wafer pieces (thickness 800 μm). One side of the resin sheet of the resultant laminate was adhered on the wafer piece through vacuum bonding at a laminate temperature of 130 degrees C. (laminator: “V-130” manufactured by Nikko-Materials Co., Ltd.; reached pressure 100 Pa, time 30 seconds). Subsequently, a copper foil (size 50 mm×10 mm, thickness 150 μm, as specified by JIS H 3100) was adhered on the other side of the resin sheet through vacuum bonding under the same conditions as the above. It should be noted that the second release member and the first release member of the resin sheet of the laminate were released before the resin sheet was adhered on the Si wafer and copper plate, respectively, Subsequently, the resin composition was cured under heat-curing conditions (at 200 degrees C. for four hours) to prepare a sample. Using a tensile tester (“Autograph AG-IS” manufactured by Shimadzu Corporation), the copper foil was peeled off from the cured resin sheet at a peeling rate of 50 mm/min and peel angle of 90 degrees to measure the peel-strength (unit: N/10 mm) between the copper foil and the cured resin sheet. The measurement was performed under an environment of 25 degrees C. and relative humidity of 50%. The obtained results are shown in Table 1.

TABLE 1

| | Heat-Curable Component | | | | | | | | Binder |
|---|---|---|---|---|---|---|---|---|---|
| | First | First | First | Second | | | | | Component |
| | Maleimide | Maleimide | Maleimide | Maleimide | Allyl | Curing | Epoxy | Phenol | Binder |
| | Resin-1 | Resin-2 | Resin-3 | Resin | Resin | Catalyst | Resin | Resin | Resin-1 |
| Ex. 1 | — | 15.32 | | 5.38 | — | — | — | — | 5.00 |
| Ex. 2 | 18.78 | — | — | — | 1.92 | — | — | — | 5.00 |
| Ex. 3 | — | 18.98 | — | — | 1.72 | — | — | — | 5.00 |
| Ex. 4 | — | 15.32 | — | 5.38 | — | — | — | — | — |
| Ex. 5 | — | 15.18 | — | 5.05 | — | — | — | — | — |
| Ex. 6 | — | 15.18 | — | 5.05 | — | — | — | — | — |
| Ex. 7 | — | — | 17.12 | — | 3.11 | — | — | — | — |
| Comp. 1 | — | — | — | 16.17 | 4.53 | — | — | — | 5.00 |
| Comp. 2 | — | — | — | — | — | 0.03 | 11.47 | 9.20 | — |
| | | | | | Adhesion- | | Evaluation Results | | |
| | | | | Coupling | Imparting | | Resin Sheet (Cured Product) | | |
| | | | Inorganic | Agent | Agent | | Displacement | Storage | |
| | Binder Component | | Filler | Silane | Adhesion- | | When Being | Modulus at | Peel |
| | Binder | Binder | Silica | Coupling | Imparting | | Torn Apart | 250° C. | Strength |
| | Resin-2 | Resin-3 | Filler | Agent | Agent | Total | (mm) | (Mpa) | (N/10 mm) |
| Ex. 1 | — | — | 74.00 | 0.30 | — | 100.00 | 1.04 | 677 | 1.09 |
| Ex. 2 | — | — | 74.00 | 0.30 | — | 100.00 | 1.27 | 527 | 5.69 |
| Ex. 3 | — | — | 74.00 | 0.30 | — | 100.00 | 1.27 | 358 | 3.44 |
| Ex. 4 | 5.00 | — | 74.00 | 0.30 | — | 100.00 | 1.00 | 371 | 2.36 |
| Ex. 5 | 5.00 | — | 74.00 | 0.30 | 0.47 | 100.00 | 1.15 | 391 | 7.78 |
| Ex. 6 | — | 5.00 | 74.00 | 0.30 | 0.47 | 100,00 | 1.61 | 388 | 15.31 |
| Ex. 7 | 5.00 | — | 74.00 | 0.30 | 0.47 | 100.00 | 1.30 | 155 | 5.94 |
| Comp. 1 | — | — | 74.00 | 0.30 | — | 100.00 | 0.29 | 2309 | 5.20 |
| Comp. 2 | 5.00 | — | 74.00 | 0.30 | — | 100.00 | 0.44 | 60 | 2.85 |

It is found that the resin sheets according to Examples 1 to 7 are excellent in terms of all of the flexibility, elastic modulus at 250 degrees C., and peel-strength of the cured product. Accordingly, it is confirmed that the resin sheets according to Examples 1 to 7 can provide a cured product with sufficient flexibility and heat resistance.

It is found that Comparative 1, which is different from Example 1 in the absence of the first maleimide resin, is inferior to Example 1 in terms of flexibility of the cured product.

It is found that Comparative 2, which uses epoxy resin sheet, is low in terms of the elastic modulus at 250 degrees C. and inferior in the heat resistance as compared with Examples 1 to 7.

### EXPLANATION OF CODES

1 . . . laminate, 2 . . . first release member, 3 . . . resin sheet, 4 . . . second release member

1. A resin sheet made of a resin composition comprising a (A) heat-curable component, wherein
the (A) heat-curable component comprises a (A1) first maleimide resin, and
the (A1) first maleimide resin is a maleimide resin having two or more maleimide groups in one molecule, at least a pair of the maleimide groups being bonded by a binding group whose main chain comprises four or more methylene groups.

2. The resin sheet according to claim 1, wherein
the (A1) first maleimide resin is a maleimide resin that is liquid at 25 degrees C.

3. The resin sheet according to claim 1, wherein
the (A1) first maleimide resin is represented by a formula (A1) below, 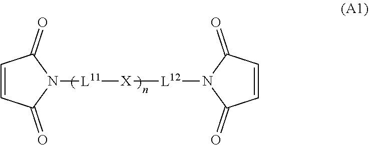
where, in the formula (A1): n is an integer of 0 or more; L¹¹ and L¹² are each independently a substituted or unsubstituted alkylene group having 4 or more carbon atoms, at least one of —CH₂— in the alkylene group being optionally replaced by —CH₂—O— or —O—CH₂—; and X is each independently a group not comprising a substituted or unsubstituted alkylene group having 4 or more carbon atoms whose at least one of —CH₂— is optionally replaced by —CH₂—O— or —O—CH₂—.

4. The resin sheet according to claim 3, wherein
the alkylene group in the formula (A1) is substituted by a substituent, the substituent being an alkyl group having 1 to 10 carbon atoms or an alkoxy group having 1 to 10 carbon atoms.

5. The resin sheet according to claim 1, wherein
the (A) heat-curable component further comprises a (A2) second maleimide resin different from the (A1) first maleimide resin.

6. The resin sheet according to claim 5, wherein
a mass ratio (A1/A2) of the (A1) first maleimide resin to the (A2) second maleimide resin is 0.5 or more.

7. The resin sheet according to claim 6, wherein
a total content of the (A1) first maleimide resin and the (A2) second maleimide resin in the (A) heat-curable component is 60 mass % or more in terms of a total solid content of the (A) heat-curable component.

8. The resin sheet according to claim 1, wherein
the (A) heat-curable component further comprises a (A3) allyl resin.

9. The resin sheet according to claim 1, wherein
the resin composition further comprises a (B) binder component comprising at least one resin selected from the group consisting of a phenoxy resin and a polyamide-imide resin.

10. The resin sheet according to claim 1, wherein
the resin composition further comprises a triazine compound as an adhesion-imparting agent.

11. The resin sheet according to claim 10, wherein
the triazine compound is an imidazole compound having a triazine skeleton.

12. The resin sheet according to claim 1, wherein
a peel-strength after being thermally cured is 2.0 N/10 mm or more.

13. The resin sheet according to claim 1, wherein
the resin sheet is usable for sealing a semiconductor element, or as a component interposed between the semiconductor element and another electronic component.

14. The resin sheet according to claim 1, wherein
the resin sheet is usable for sealing a power semiconductor element, or as a component interposed between the power semiconductor element and another electronic component.

15. The resin sheet according to claim 1, wherein
the resin sheet is usable for sealing a semiconductor element made of at least one of silicon carbide or gallium nitride or as a component interposed between the semiconductor element made of at least one of silicon carbide or gallium nitride, and another electronic component.
